(19) United States
(12) Patent Application Publication
(10) Pub. No.: US 2024/0062992 A1
(43) Pub. Date: Feb. 22, 2024

(54) PLASMA POST-PROCESSING APPARATUS AND PLASMA POST-PROCESSING METHOD USING THE SAME

(71) Applicant: Samsung Display Co., Ltd., Yongin-si (KR)

(72) Inventors: DAESOO KIM, Yongin-si (KR); DAEWON CHOI, Yongin-si (KR); SANGGAB KIM, Yongin-si (KR)

(73) Assignee: Samsung Display Co., Ltd., Yongin-si (KR)

(21) Appl. No.: 18/327,211

(22) Filed: Jun. 1, 2023

(30) Foreign Application Priority Data
Aug. 18, 2022 (KR) 10-2022-0103427

(51) Int. Cl. H01J 37/32; H01L 21/3213

(52) U.S. Cl. CPC H01J 37/3244; H01L 21/32136; H01J 2237/334

(57) ABSTRACT

Disclosed is a plasma post-processing apparatus including a chamber, a stage disposed inside of the chamber, a work substrate disposed on the stage, diffusers each of which increases in width in a direction away from the work substrate and having holes, and disposed above the stage, transfer pipes respectively connected to the diffusers, and plasma generators respectively connected to pipes that supply process gases and are respectively connected to the transfer pipes, and a diameter of the holes defined in a diffuser disposed at a center of the work substrate among the diffusers is less than a diameter of holes defined in each of remaining diffusers among the diffusers.

### CROSS-REFERENCE TO RELATED APPLICATIONS

This application claims priority to and benefits of Korean Patent Application No. 10-2022-0103427 filed on Aug. 18, 2022, in the Korean Intellectual Property Office, the entire contents of which are incorporated herein by reference.

### BACKGROUND

### 1. Technical Field

Embodiments described herein relate to a plasma post-processing apparatus and a plasma post-processing method using the same, and, also relate to a plasma post-processing apparatus and a plasma post-processing method using the same that perform a corrosion prevention treatment and a photoresist layer removal using a plasma technique.

### 2. Description of the Related Art

Conductive lines included in a display panel may be formed by patterning a conductive layer via an etching process. In this regard, a process gas provided during the etching process may remain in the patterned conductive lines, and the remaining process gas may cause corrosion of the conductive lines. Therefore, after the etching process, a post-processing process for preventing the corrosion of the conductive lines is required.

A post-processing step of removing a photoresist layer used in the etching process is performed as a separate process.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a plasma post-processing apparatus and a plasma post-processing method using the same that may perform a corrosion prevention treatment step and a step of removing a photoresist layer in the same chamber.

Embodiments provide a plasma post-processing apparatus including at least one diffuser capable of uniformly spraying plasma.

According to an embodiment, a plasma post-processing apparatus may include a chamber; a stage disposed inside of the chamber; wherein a work substrate is disposed on the stage; diffusers each of which increases in width in a direction away from the work substrate and each of the diffusers having holes, and disposed above the stage; transfer pipes respectively connected to the diffusers; and plasma generators respectively connected to pipes that supply process gases and are respectively connected to the transfer pipes, wherein a diameter of the holes defined in a diffuser disposed at a center of the work substrate among the diffusers is less than a diameter of holes defined in each of the remaining diffusers among the diffusers.

The diameter of the holes defined in the diffuser disposed at the center of the work substrate among the diffusers may be substantially equal to or greater than about 2 Φ and substantially equal to or less than about 15 Φ, and the diameter of the holes defined in each of the remaining diffusers may be substantially equal to or greater than about 2 Φ and substantially equal to or less than about 30 Φ.

A diameter of each of the holes may increase gradually in the direction away from the work substrate.

Each of the diffusers may contain an aluminum oxide.

Each of the diffusers may include an outer surface, an inner surface opposite to the outer surface, and a connecting surface disposed between the outer surface and the inner surface, the holes may be defined through the inner surface from the outer surface, and an internal space may be defined inwardly of the inner surface.

Each of the diffusers may have a substantially hemispherical shape substantially convex in a direction toward the work substrate.

Each of the diffusers may have a substantially conical shape substantially convex in a direction toward the work substrate.

The process gases provided to the pipes may be at least one of water vapor (H₂O), oxygen (O₂), carbon tetrafluoride (CF₄), argon (Ar), nitrogen (N₂), and helium (He).

The plasma post-processing apparatus may further include a backing plate having first holes and connected with the diffusers; an insulator having second holes respectively overlapping the first holes and disposed on the backing plate; and a cooling plate having third holes respectively overlapping the second holes and disposed on the insulator.

One of the transfer pipes may be formed with one of the first holes, one of the second holes, and one of the third holes aligned with each other.

At least one of the diffusers may include a first portion where the holes are defined and a second portion extending from the first portion and where the holes are not defined, and the second portion may be connected to a corresponding transfer pipe.

According to an embodiment, a plasma post-processing apparatus may include a chamber; a stage disposed inside of the chamber, wherein a work substrate is disposed on the stage; a diffuser having a substantially hemispherical shape substantially convex in a direction toward the work substrate, the diffuser having holes, and disposed above the stage; a backing plate having a first hole and connected with the diffuser; an insulator having a second hole overlapping the first hole and disposed on the backing plate; a cooling plate having a third hole overlapping the second hole and disposed on the insulator; and a plasma generator connected to pipes that supply process gases, the first hole, the second hole, and the third hole aligned with each other are defined as a transfer pipe, and the plasma generator is connected to the transfer pipe.

The diffuser may contain an aluminum oxide.

The diffuser may include a first portion where the holes are defined and a second portion extending from the first portion and where the holes are not defined, and the second portion may be connected to the transfer pipe.

The process gases provided to the pipes may be at least one of water vapor (H₂O), oxygen (O₂), carbon tetrafluoride (CF₄), argon (Ar), nitrogen (N₂), and helium (He).

A diameter of each of the holes of the diffuser may increase gradually in a direction away from the work substrate.

The diffuser may include an outer surface, an inner surface opposite to the outer surface, and a connecting surface disposed between the outer surface and the inner surface and connected to the backing plate, the holes may be defined through the inner surface from the outer surface, and a substantially hemispherical internal space may be defined inwardly of the inner surface.

A diameter of the holes may be substantially equal to or greater than about 2 Φ and substantially equal to or less than about 30 Φ.

According to an embodiment, a plasma post-processing method may include forming a conductive pattern by etching a conductive layer formed on a work substrate; and performing a corrosion prevention treatment on the conductive pattern, wherein the performing of the corrosion prevention treatment may include generating first radicals by a plasma generator by receiving water vapor (H₂O); and providing the first radicals to a transfer pipe and spraying the first radicals by a diffuser, and the diffuser has a substantially hemispherical shape substantially convex in a direction toward the work substrate and has holes.

The plasma post-processing method may further include removing a photoresist layer disposed on the conductive pattern, wherein the removing of the photoresist layer may include generating second radicals by the plasma generator by receiving oxygen (O₂); and providing the second radicals to the transfer pipe and spraying the second radicals to the diffuser, and the performing of the corrosion prevention treatment and the removing of the photoresist layer may be performed as continuous processes in a same chamber.

### BRIEF DESCRIPTION OF THE DRAWINGS

The above and other objects and features of the disclosure will become apparent by describing in detail embodiments thereof with reference to the accompanying drawings in which:

FIG. 1 is a schematic cross-sectional view of a plasma post-processing apparatus according to an embodiment.

FIG. 2 is a schematic perspective view of a diffuser according to an embodiment.

FIG. 3 is a schematic plan view showing dispersion of radicals sprayed from a diffuser according to an embodiment.

FIG. 4 is a schematic perspective view of a diffuser according to an embodiment.

FIG. 5 is a schematic perspective view of a diffuser according to an embodiment.

FIG. 6 is a schematic perspective view of a diffuser according to an embodiment.

FIG. 7 is a schematic cross-sectional view of a plasma post-processing apparatus according to an embodiment.

FIG. 8 is a schematic cross-sectional view showing diffusers and transfer pipes according to an embodiment.

FIG. 9 is a schematic plan view illustrating arrangement relationships of diffusers and a backing plate according to an embodiment.

FIG. 10 is a schematic cross-sectional view of a display panel according to an embodiment.

FIGS. 11A to 11F are schematic cross-sectional views showing a plasma post-processing method according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the specification, when a component (or an area, a layer, a portion, and the like) is referred to as being “on”, “connected to”, or “coupled to” another component, it means that the component may be directly disposed/connected/coupled on another component or a third component or other components may be disposed between the component and another component. It will be understood that the terms “connected to” or “coupled to” may include a physical or electrical connection or coupling.

Like reference numerals refer to like components. In the drawings, thicknesses, ratios, and dimensions of components are exaggerated for effective description of technical content.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Terms such as first, second, and the like may be used to describe various components, but the components should not be limited by the terms. The above terms are used only for the purpose of distinguishing one component from another. For example, without departing from the scope of the disclosure, a first component may be named as a second component, and similarly, the second component may also be named as the first component.

Terms such as “beneath”, “below”, “on”, “above” are used to describe the relationship of the components shown in the drawings. The above terms are relative concepts, and are described with reference to directions indicated in the drawings but are not limited thereto.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

It should be understood that terms such as “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to the drawings.

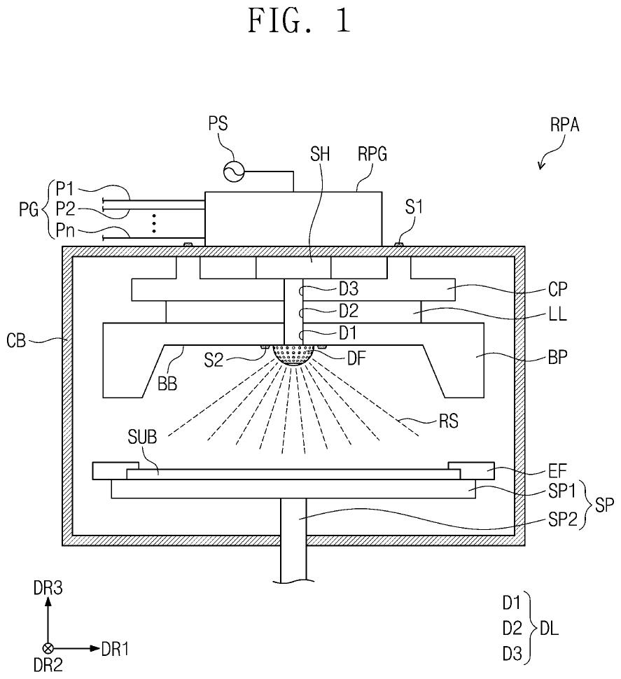

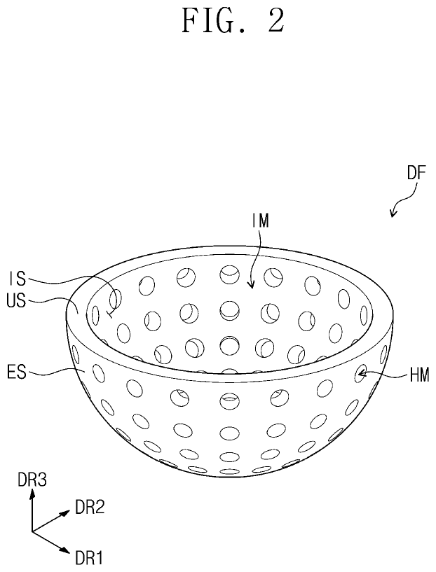

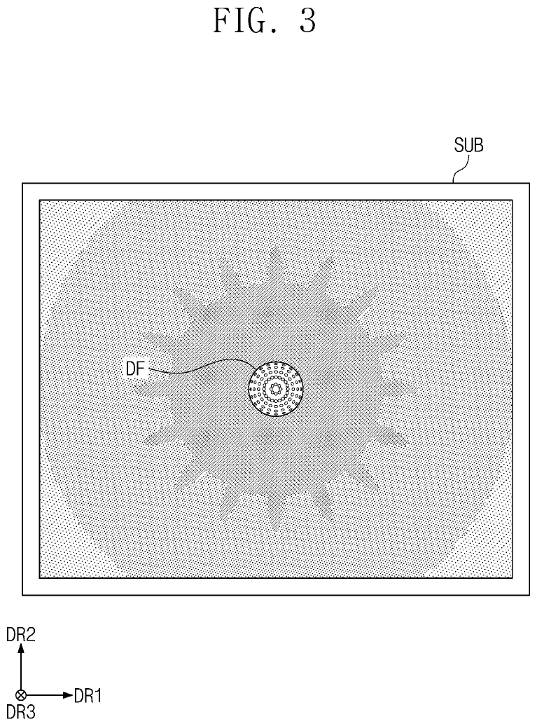

FIG. 1 is a schematic cross-sectional view of a plasma post-processing apparatus according to an embodiment. FIG. 2 is a schematic perspective view of a diffuser according to an embodiment. FIG. 3 is a schematic plan view showing dispersion of radicals sprayed from a diffuser according to an embodiment.

A plasma post-processing apparatus RPA according to the disclosure may be an apparatus used to perform a corrosion prevention treatment of patterned conductive patterns after etching a conductive layer into the conductive patterns in a step of forming conductive lines included in a display panel DP (see FIG. 10). The plasma post-processing apparatus RPA according to the disclosure may be an apparatus used to remove a photoresist layer used in the etching process.

The plasma post-processing apparatus RPA according to the disclosure may include a chamber CB, a susceptor SP, a diffuser DF, a backing plate BP, an insulator LL, a cooling plate CP, a plasma generator RPG, and a transfer pipe DL.

An internal space of the chamber CB in which a post-processing process of a work substrate SUB may be performed may be defined. Components necessary for an operation of the plasma post-processing apparatus RPA may be disposed in the internal space of the chamber CB. During a process of the plasma post-processing apparatus RPA, the internal space of the chamber CB may be sealed from the outside. The chamber CB may block an inflow of external air.

In the chamber CB according to an embodiment, a portion of the chamber CB may be opened and closed for transfer of the work substrate SUB or the like within the spirit and the scope of the disclosure. A portion of a side surface of the chamber CB may be opened and closed. One region of the chamber CB according to an embodiment may be electrically connected to an external ground terminal.

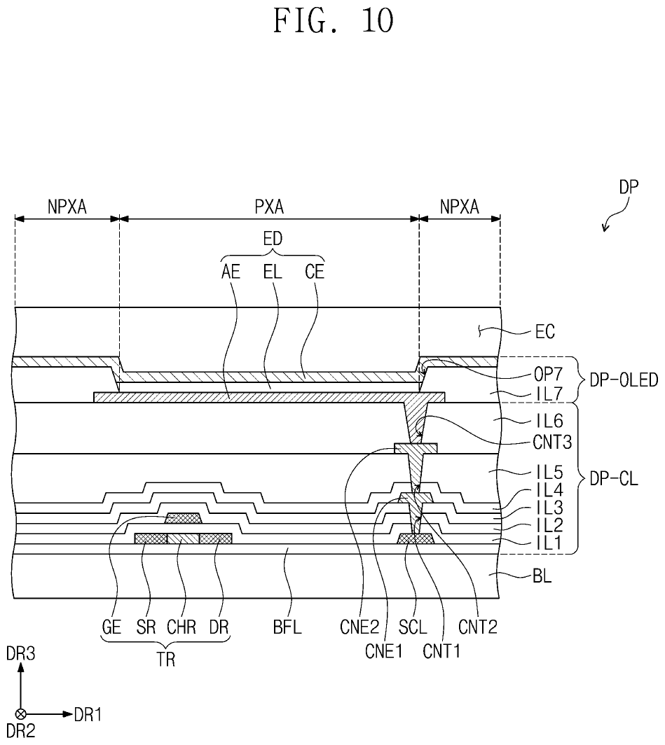

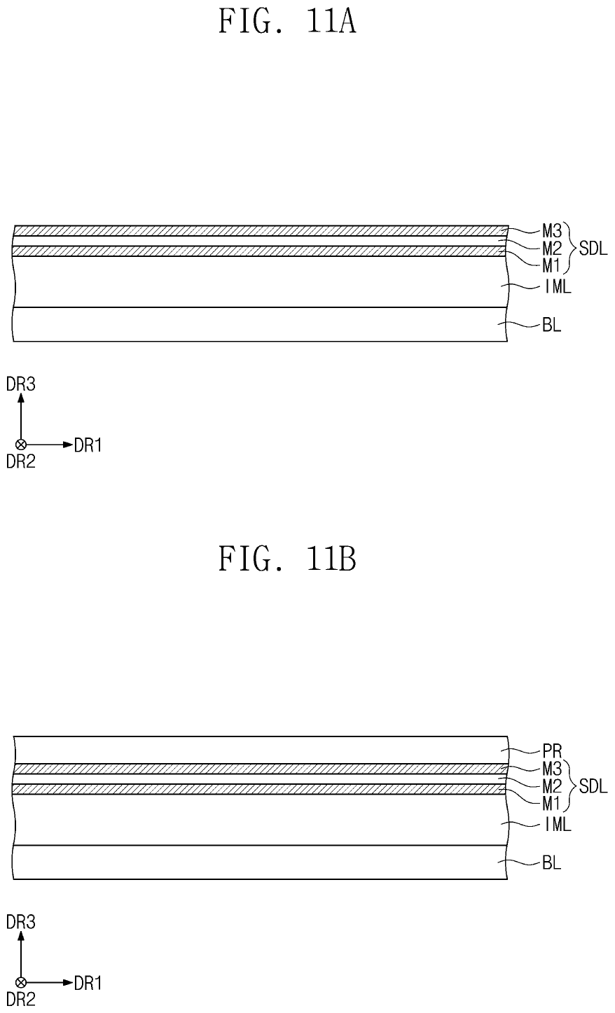

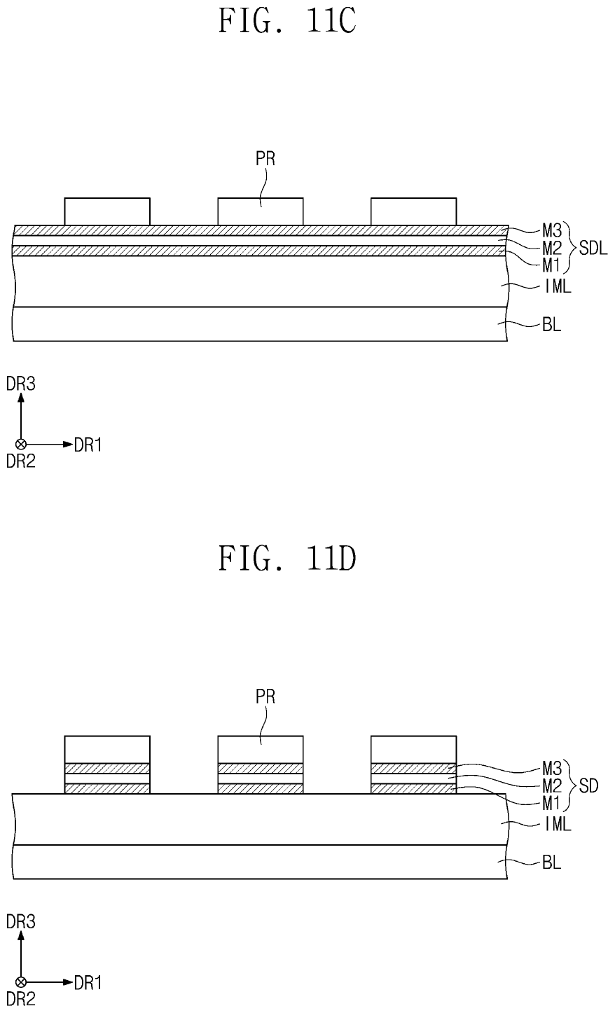

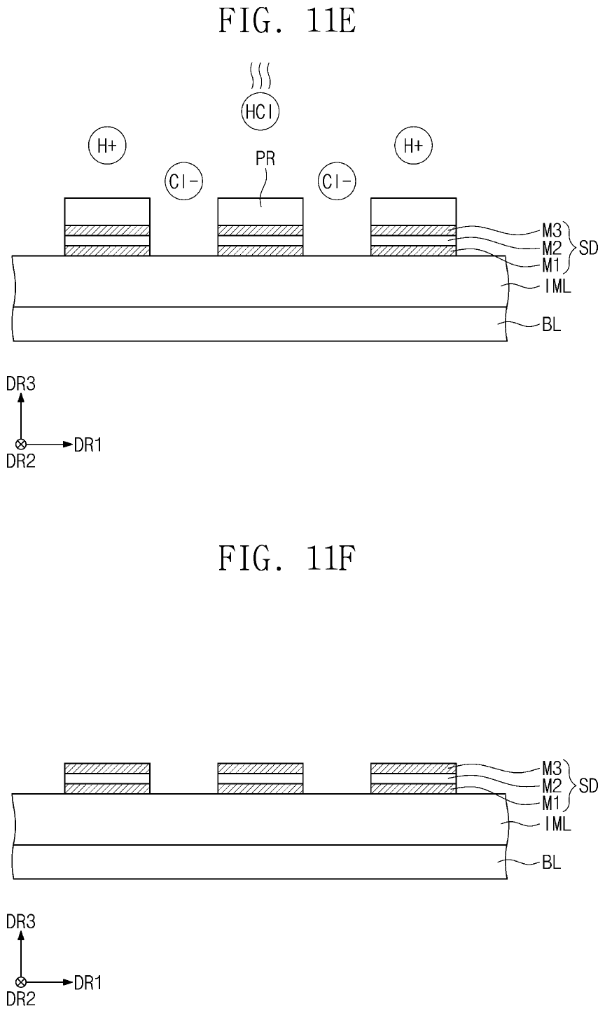

The susceptor SP may support the work substrate SUB. The work substrate SUB according to the disclosure may be provided in a state of including conductive patterns SD (see FIG. 11D) disposed on an insulating layer IML (see FIG. 11A) and a photoresist layer PR (see FIG. 11D) disposed on the conductive patterns SD. The conductive patterns SD (see FIG. 11D) may be in a state of being patterned by an etching process in a conductive layer SDL (see FIG. 11B).

The susceptor SP may include a stage SP1 that supports the work substrate SUB, and a transfer portion SP2 connected to the stage SP1 and extending through a bottom surface of the chamber CB. The work substrate SUB may be disposed on a top surface of the stage SP1. The stage SP1 and the transfer portion SP2 may be provided separately from each other or may be integral with each other. Shapes of the stage SP1 and the transfer portion SP2 may be variously changed based on the components included in the plasma post-processing apparatus RPA.

The stage SP1 may be provided as a square or circular plate to support the work substrate SUB. Although not shown, the susceptor SP may include a heating line capable of heating the work substrate SUB and/or a cooling line capable of cooling the work substrate SUB. The heating line and/or the cooling line may be embedded in the stage SP1.

By way of example, the transfer portion SP2 may allow the work substrate SUB to reach a process position by vertically ascending or vertically descending along a third direction DR3. The stage SP1 may move in a same direction based on the movement of the transfer portion SP2. For example, in case that the work substrate SUB is transferred from an external space to the internal space of the chamber CB through the side surface of the chamber CB, the transfer portion SP2 may vertically ascend. As a result, the work substrate SUB may be placed on the stage SP1. Thereafter, as the transfer portion SP2 descends, the work substrate SUB may reach the process position.

The susceptor SP may further include edge frames EF for fixing side surfaces of the work substrate SUB. The edge frame EF may be positioned to cover an edge of the work substrate SUB. The susceptor SP may be connected to the external ground terminal. The transfer portion SP2 may be coupled to or connected to the bottom surface of the chamber CB, and may be electrically connected to a bottom surface DS.

The diffuser DF may be disposed above the work substrate SUB. The diffuser DF may be disposed on a back surface BB of the backing plate BP, and may be connected to the transfer pipe DL. According to the disclosure, radicals RS of plasma generated in the plasma generator RPG may be sprayed onto the work substrate SUB via the diffuser DF. As the work substrate SUB is enlarged, a uniform dispersion of the radicals RS sprayed from the diffuser DF is required.

A selectable separation space into which the radicals RS may be sprayed may be defined between the work substrate SUB and the diffuser DF. The diffuser DF may contain one of aluminum, an aluminum oxide (Al₂O₃), inconel, and Hastelloy.

Referring to FIG. 2, the diffuser DF according to an embodiment may include an outer surface ES adjacent to the work substrate SUB, an inner surface IS opposite the outer surface ES, and a connecting surface US disposed between the outer surface ES and the inner surface IS and coupled to or connected to the back surface BB of the backing plate BP.

Holes HM extending through the inner surface IS from the outer surface ES may be defined in the diffuser DF. The holes HM may be defined to be spaced apart from each other. A selectable internal space IM corresponding to an outer shape of the diffuser DF may be defined inside the inner surface IS of the diffuser DF. The diffuser DF according to an embodiment may have a shape of a hemisphere convex in a direction toward the work substrate SUB. Accordingly, a shape of the internal space IM may also be the hemispherical shape. The radicals RS of the plasma generated in the plasma generator RPG may be provided to the internal space IM via the transfer pipe DL and may be sprayed onto the work substrate SUB through the holes HM.

Referring to FIG. 3, the dispersion of the radicals RS of the plasma generated in the plasma generator RPG sprayed through the holes HM of the diffuser DF is illustrated by way of example.

The radicals RS according to the disclosure may pass through the holes HM with straightness in an initial stage of being sprayed onto the work substrate SUB through the holes HM. Accordingly, in a given region, the radicals RS may be sprayed with the straightness in a direction in which the holes HM are defined.

As the diffuser DF according to the disclosure has the hemispherical shape, the initial radicals RS that were sprayed with the straightness may be sprayed onto the work substrate SUB while forming a region in which initial radicals RS overlap each other. Accordingly, the radicals RS adjacent to the work substrate SUB may be sprayed over an entire region of the work substrate SUB. Accordingly, the plasma post-processing apparatus RPA having improved dispersion of the radicals RS may be provided.

Again, referring to FIG. 1, the backing plate BP may be positioned above the susceptor SP, and may be spaced apart from the susceptor SP by a selectable spacing. The backing plate BP may contain a metallic material.

The backing plate BP may be connected to an external power supply. Accordingly, the backing plate BP may receive power supplied from the power supply. The power applied to the backing plate BP may be transmitted to the diffuser DF connected to the backing plate BP. The diffuser DF may be disposed on the back surface BB of the backing plate BP. The diffuser DF may be fixed to the back surface BB of the backing plate BP via a fastening member (for example, a bolt or the like).

The insulator LL may be placed on the backing plate BP. The insulator LL may prevent the power applied to the backing plate BP from leaking through the chamber CB. The backing plate BP and the cooling plate CP may be insulated from each other.

The cooling plate CP is placed on the insulator LL. The cooling plate CP provides a function of lowering an internal temperature of the chamber CB so as to prevent a process temperature from being excessively increased in the post-processing process. Accordingly, deformation of the work substrate SUB may be prevented during the post-processing process. A cooling line into which cooling water or cooled air is injected or the like may be disposed inside the cooling plate CP.

According to an embodiment, the cooling plate CP may be coupled to or connected to a top surface of the chamber CB via a fastening member S1 (for example, the bolt or the like). However, the disclosure may not be limited thereto, and the cooling plate CP may be disposed inside the chamber CB and coupled to or connected to the chamber CB via a separate support member or the like disposed inside the chamber CB, and a fixing method of the cooling plate CP is not limited to a method.

A first hole D1 may be defined in the backing plate BP according to the disclosure. The first hole D1 may extend through the backing plate BP. A second hole D2 overlapping the first hole D1 may be defined in the insulator LL. The second hole D2 may extend through the insulator LL. A third hole D3 overlapping the second hole D2 may be defined in the cooling plate CP. The third hole D3 may extend through the cooling plate CP. The first hole D1, the second hole D2, and the third hole D3 may be aligned with each other. According to the disclosure, the first hole D1, the second hole D2, and the third hole D3 aligned with each other may be defined as one transfer pipe DL. The radicals RS of the plasma generated in the plasma generator RPG may be transferred to the diffuser DF via the transfer pipe DL.

The backing plate BP, the insulator LL, and the cooling plate CP may be coupled to or connected to each other via a fastening member S2 (for example, the bolt or the like) in the state in which the first hole D1, the second hole D2, and the third hole D3 are aligned with each other. Accordingly, during the post-processing process, the aligned state of the first hole D1, the second hole D2, and the third hole D3 may be maintained, and accordingly, the radicals RS may be provided to the diffuser DF at a uniform spray speed and/or spray amount.

According to an embodiment, a supply portion SH connected to the transfer pipe DL may be further included. The supply portion SH may be disposed on the top surface of the chamber CB, and may be disposed between the plasma generator RPG and the transfer pipe DL. The supply portion SH may adjust a flow of the radicals RS provided from the plasma generator RPG, or check a state of the radicals RS that meets process conditions. According to an embodiment, the supply portion SH may be omitted, and the transfer pipe DL may be connected to or directly connected to the plasma generator RPG.

The plasma generator RPG may be disposed outside of the chamber CB. The plasma generator RPG may be connected to a gas pipe PG, and connected to a power supply PS so as to receive a selectable current. The gas pipe PG may include pipes P1, P2, to Pn. Different process gases may be supplied to the pipes P1, P2, to Pn, respectively. According to an embodiment, the process gases respectively provided to the pipes P1, P2, to Pn may be water vapor (H₂O), oxygen (O₂), carbon tetrafluoride (CF₄), argon (Ar), nitrogen (N₂), and helium (He). The different process gases respectively provided to the pipes P1, P2, to Pn may be individually supplied based on a purpose of the process. The plasma generator RPG is not limited to one apparatus as long as it generates the plasma by receiving the gas.

According to an embodiment, a process gas provided to the plasma generator RPG in the corrosion prevention treatment step of the post-processing process of the work substrate SUB may be the water vapor (H₂O). The radicals RS generated via the water vapor (H₂O) may be combined with chlorine ions (Cl⁻) that affect the corrosion on the work substrate SUB and may be discharged as hydrochloric acid (HCl).

A process gas provided to the plasma generator RPG in a step (an ashing step) of removing the photoresist layer PR (see FIG. 11E) during the post-processing process of the work substrate SUB may be the oxygen (O₂). The radicals RS generated via the oxygen (O₂) may react with the photoresist layer PR to remove the photoresist layer PR.

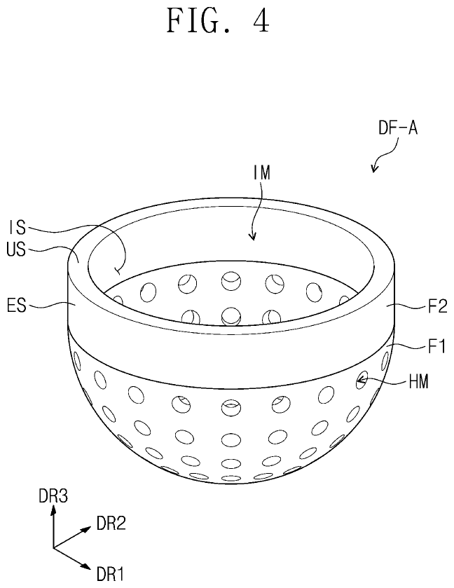

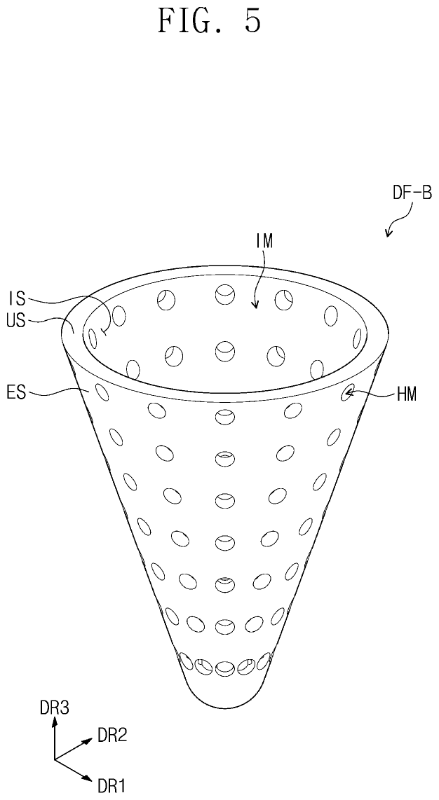

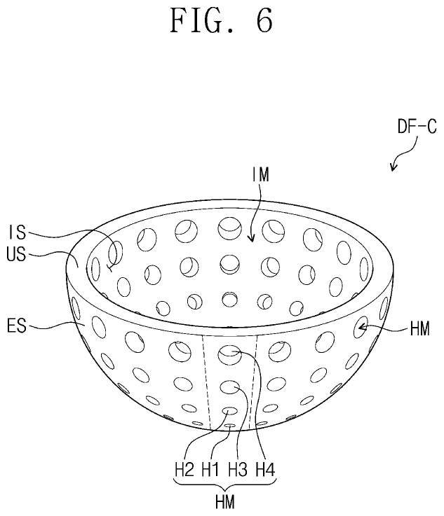

FIG. 4 is a schematic perspective view of a diffuser according to an embodiment. FIG. 5 is a schematic perspective view of a diffuser according to an embodiment. FIG. 6 is a schematic perspective view of a diffuser according to an embodiment. The same/similar reference numerals are used for the same/similar components as those described with reference to FIGS. 1 to 3, and duplicate descriptions thereof are omitted.

Referring to FIG. 4, a diffuser DF-A according to an embodiment may include the outer surface ES, the inner surface IS opposite to the outer surface ES, and the connecting surface US disposed between the outer surface ES and the inner surface IS and coupled to or connected to the back surface BB (see FIG. 1) of the backing plate BP (see FIG. 1).

The holes HM extending through the inner surface IS from the outer surface ES may be defined in the diffuser DF-A. The holes HM may be defined to be spaced apart from each other. The selectable internal space IM corresponding to an outer shape of the diffuser DF-A may be defined inside the inner surface IS of the diffuser DF-A.

The diffuser DF-A according to an embodiment may include a first portion F1 and a second portion F2. The holes HM may be defined in the first portion F1 and not defined in the second portion F2. The second portion F2 may provide the connecting surface US coupled to or connected to the back surface BB (see FIG. 1) of the backing plate BP (see FIG. 1). The diffuser DF-A may have a shape of the hemisphere convex in the direction toward the work substrate SUB (see FIG. 1). Accordingly, the shape of the internal space IM may also be the hemispherical shape.

Referring to FIG. 5, a diffuser DF-B according to an embodiment may include the outer surface ES, the inner surface IS opposite to the outer surface ES, and the connecting surface US disposed between the outer surface ES and the inner surface IS and coupled to or connected to the back surface BB (see FIG. 1) of the backing plate BP (see FIG. 1). The holes HM extending through the inner surface IS from the outer surface ES may be defined in the diffuser DF-B. The holes HM may be defined to be spaced apart from each other. The selectable internal space IM corresponding to an outer shape of the diffuser DF-B may be defined inside the inner surface IS of the diffuser DF-B.

The diffuser DF-B according to an embodiment may have a shape of a cone protruding in the direction toward the work substrate SUB (see FIG. 1). Accordingly, the internal space IM may also have the conical shape.

Referring to FIG. 6, a diffuser DF-C according to an embodiment may include the outer surface ES, the inner surface IS opposite to the outer surface ES, and the connecting surface US disposed between the outer surface ES and the inner surface IS and coupled to or connected to the back surface BB (see FIG. 1) of the backing plate BP (see FIG. 1).

The holes HM extending through the inner surface IS from the outer surface ES may be defined in the diffuser DF-C. The holes HM may be defined to be spaced apart from each other. The selectable internal space IM corresponding to an outer shape of the diffuser DF-C may be defined inside the inner surface IS of the diffuser DF-C.

According to an embodiment, the holes HM may have diameters different in a direction away from the work substrate SUB (see FIG. 1). For convenience of illustration, one group of holes arranged or disposed in the direction away from the work substrate SUB (see FIG. 1) will be described as an example.

The hole group may include first to fourth holes H1, H2, H3, and H4. The first to fourth holes H1, H2, H3, and H4 may be sequentially arranged or disposed in the direction away from the work substrate SUB (see FIG. 1), and diameters thereof may progressively increase in a direction from the first to fourth holes H1, H2, H3, and H4. Therefore, the diameter of the first hole H1 closest to the work substrate SUB may be the smallest, and the diameter of the fourth hole H4 defined the farthest from the work substrate SUB may be the largest.

As the radicals RS (see FIG. 1) sprayed from the transfer pipe DL (see FIG. 1) have the straightness, straightness of the radicals RS sprayed through the first hole H1 is the strongest, and the straightness of the sprayed radicals RS gradually decreases in a direction from the second to fourth holes H2, H3, and H4.

According to an embodiment, as the diffuser DF-C including the holes HM whose diameters increase in the direction away from the work substrate SUB (see FIG. 1) is included, the radicals RS may be uniformly sprayed over the entire region of the work substrate SUB. Accordingly, the plasma post-processing apparatus RPA (see FIG. 1) having the improved dispersion of the radicals RS may be provided.

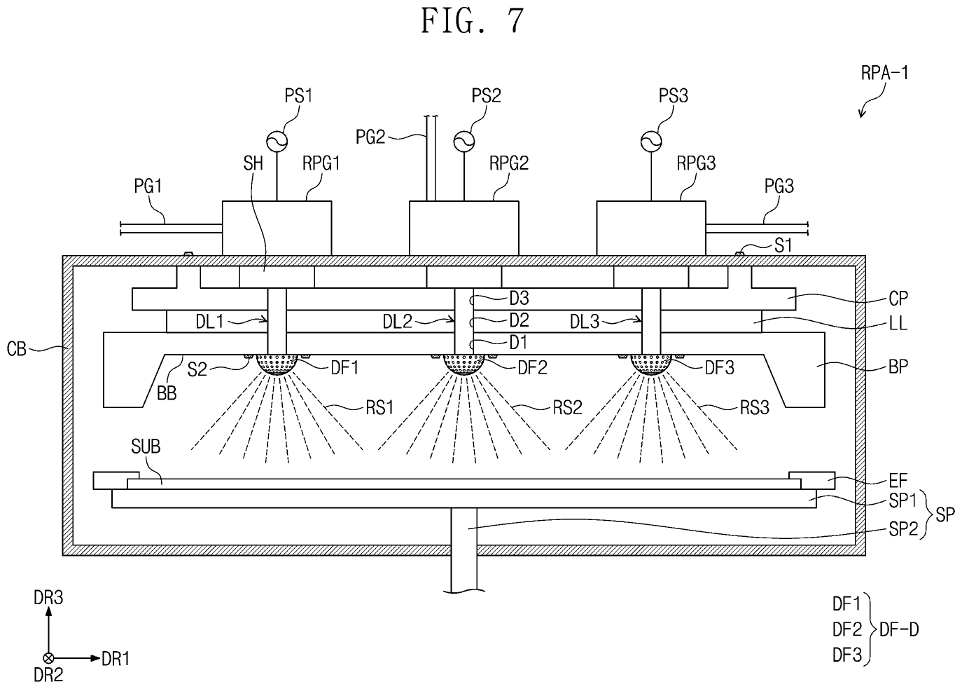

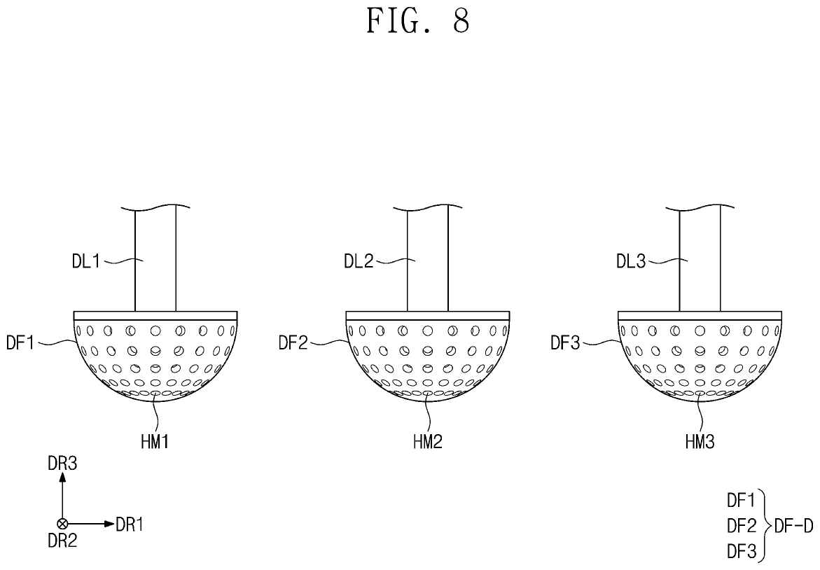

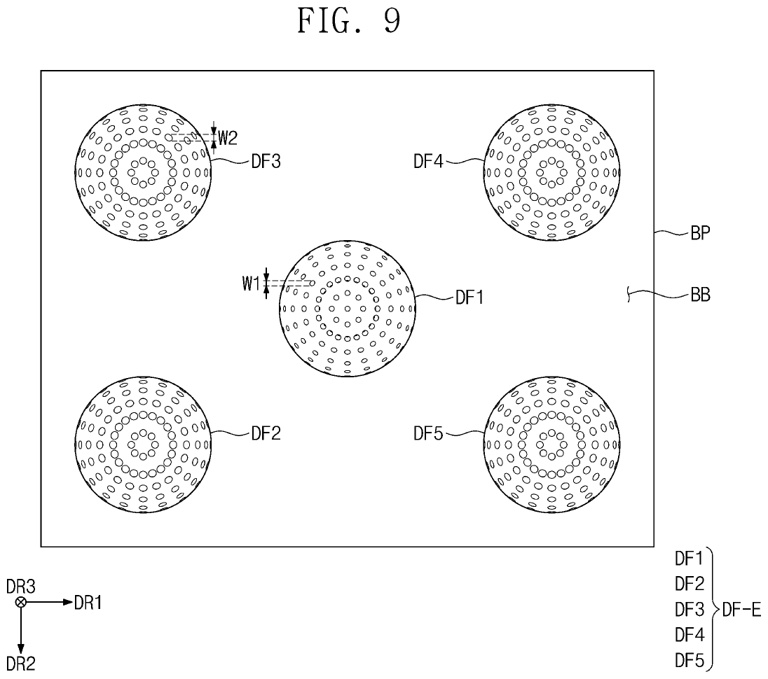

FIG. 7 is a schematic cross-sectional view of a plasma post-processing apparatus according to an embodiment. FIG. 8 is a schematic cross-sectional view showing diffusers and transfer pipes according to an embodiment. FIG. 9 is a schematic plan view illustrating arrangement relationships of diffusers and a backing plate according to an embodiment. The same/similar reference numerals are used for the same/similar components as those described with reference to FIGS. 1 to 3, and duplicate descriptions thereof are omitted.

Referring to FIGS. 7 and 8, a plasma post-processing apparatus RPA-1 according to the disclosure may include the chamber CB, the susceptor SP, at least one diffuser DF-D, the backing plate BP, the insulator LL, the cooling plate CP, plasma generators RPG1, RPG2, and RPG3, and transfer pipes DL1, DL2, and DL3. Description of the chamber CB, the susceptor SP, and the work substrate SUB of the plasma post-processing apparatus RPA-1 may correspond to the description of the chamber CB, the susceptor SP, and the work substrate SUB of the plasma post-processing apparatus RPA described in FIG. 1.

The at least one diffuser DF-D in an embodiment may include first to third diffusers DF1, DF2, and DF3. The first to third diffusers DF1, DF2, and DF3 may be spaced apart from each other. In an embodiment, each of the first to third diffusers DF1, DF2, and DF3 may have a shape of the hemisphere convex in the direction toward the work substrate SUB.

The first to third transfer pipes DL1, DL2, and DL3 may be respectively connected to the first to third diffusers DF1, DF2, and DF3, and the first to third plasma generators RPG1, RPG2, and RPG3 may be respectively connected to the first to third transfer pipes DL1, DL2, and DL3. FIG. 8 also includes holes HM1, HM2, and HM3.

The first holes HM1 may be defined in the first diffuser DF1, the second holes HM2 may be defined in the second diffuser DF2, and the third holes HM3 may be defined in the third diffuser DF3. Each of the holes HM1, HM2, and HM3 may correspond to the holes HM described in FIG. 2.

The first holes D1 may be defined in the backing plate BP. The first holes D1 may extend through the backing plate BP. The second holes D2 respectively overlapping the first holes D1 may be defined in the insulator LL. The second holes D2 may extend through the insulator LL. The third holes D3 respectively overlapping the second holes D2 may be defined in the cooling plate CP. The third holes D3 may extend through the cooling plate CP. Among the first to third holes D1, D2, and D3, the first hole D1, the second hole D2, and the third hole D3 overlapping each other along the third direction DR3 may be aligned with each other.

According to the disclosure, the first hole D1, the second hole D2, and the third hole D3 aligned with each other may be defined as one transfer pipe DL1, DL2, or DL3. First radicals RS1 of plasma generated in the first plasma generator RPG1 may be transferred to the first diffuser DF1 via the first transfer pipe DL1. Second radical RS2 of plasma generated in the second plasma generator RPG2 may be transferred to the second diffuser DF2 via the second transfer pipe DL2. Third radicals RS3 of plasma generated in the third plasma generator RPG3 may be transferred to the third diffuser DF3 via the third transfer pipe DL3. The first to third radicals RS1, RS2, and RS3 may contain a same material or a similar material.

First to third gas pipes PG1, PG2, and PG3 may be respectively connected to the first to third plasma generators RPG1, RPG2, and RPG3, and power supplies PS1, PS2, and PS3 may be respectively connected to the first to third plasma generators RPG1, RPG2, and RPG3. Each of the pipes PG1, PG2, and PG3 may include pipes, and different process gases may be supplied to the pipes. The process gases respectively provided to the pipes may be the water vapor (H₂O), the oxygen (O₂), the carbon tetrafluorocarbon (CF₄), the argon (Ar), the nitrogen (N₂), and the helium (He).

According to an embodiment, the first to third plasma generators RPG1, RPG2, and RPG3 may be operated individually. Therefore, depending on a size of the work substrate SUB or a position where the work substrate SUB is placed on the stage SP1, only one plasma generator may be operated. Spray speeds and/or spray amounts of the first to third radicals RS1, RS2, and RS3 provided to the work substrate SUB respectively through the first to third diffusers DF1, DF2, and DF3 may be individually controlled.

In case that the first to third radicals RS1, RS2, and RS3 are sprayed onto the work substrate SUB, a region in which the first to third radicals RS1, RS2, and RS3 overlap each other may be generated. Although it may be determined that a relatively large amount of radicals are provided in the region in which the first to third radicals RS1, RS2, and RS3 overlap each other of the work substrate SUB, in fact, the radicals may be canceled by colliding with each other in the region in which the first to third radicals RS1, RS2, and RS3 overlap each other. Therefore, even in case that the first to third diffusers DF1, DF2, and DF3 are arranged or disposed, the radicals may be uniformly sprayed onto the work substrate SUB.

According to an embodiment, as the individually operated first to third plasma generators RPG1, RPG2, and RPG3 and the first to third diffusers DF1, DF2, and DF3 respectively connected thereto are included, even in case that the work substrate SUB with a large area is provided, the radicals may be uniformly sprayed over the entire region of the work substrate SUB. Accordingly, the plasma post-processing apparatus RPA-1 with the improved radical dispersion may be provided.

Referring to FIG. 9, at least one diffuser DF-E according to an embodiment may include first to fifth diffusers DF1, DF2, DF3, DF4, and DF5. The first to fifth diffusers DF1, DF2, DF3, DF4, and DF5 may be spaced apart from each other. Each of the first to fifth diffusers DF1, DF2, DF3, DF4, and DF5 may be individually connected to a plasma generator via a corresponding transfer pipe. Thus, radicals sprayed from the first to fifth diffusers DF1, DF2, DF3, DF4, and DF5 may be individually controlled.

In an embodiment, each of the first to fifth diffusers DF1, DF2, DF3, DF4, and DF5 may have a shape of the hemisphere convex in the direction toward the work substrate SUB (see FIG. 1). FIG. 9 is a schematic plan view of the first to fifth diffusers DF1, DF2, DF3, DF4, and DF5 viewed from the back surface BB of the backing plate BP.

Among the first to fifth diffusers DF1, DF2, DF3, DF4, and DF5, the first diffuser DF1 may be disposed at a center of the work substrate SUB (see FIG. 1), and the second to fifth diffusers DF2, DF3, DF4, and DF5 may be disposed at edges outwardly of the first diffuser DF1.

According to an embodiment, holes defined in the first diffuser DF1 may have a first diameter W1, and holes defined in the second to fifth diffusers DF2, DF3, DF4, and DF5 may have a second diameter W2. In an embodiment, the first diameter W1 may be smaller than the second diameter W2. For example, the first diameter W1 may be equal to higher than 2 Φ and equal to or lower than 15 Φ, and the second diameter W2 may be equal to higher than 2 Φ and equal to or lower than 30 Φ.

According to an embodiment, in case that the radicals are individually sprayed from the first to fifth diffusers DF1, DF2, DF3, DF4, and DF5, a region with the most overlapping radicals may be adjacent to a region in which the first diffuser DF1 is disposed. As the size of the holes of the first diffuser DF1 disposed at the center of the work substrate SUB (see FIG. 1) is smaller than the size of the holes of the second to fifth diffusers DF2, DF3, DF4, and DF5 disposed at the edges, even in case that the work substrate SUB with the large area is provided, the radicals may be uniformly sprayed over the entire region of the work substrate SUB. Accordingly, the plasma post-processing apparatus RPA (see FIG. 1) having the improved radical dispersion may be provided.

FIG. 10 is a schematic cross-sectional view of a display panel according to an embodiment. FIGS. 11A to 11F are schematic cross-sectional views showing a plasma post-processing method according to an embodiment.

FIG. 10 illustrates, by way of example, a schematic cross-sectional view of the display panel DP formed via a coating process, a deposition process, a photolithography process, and the like after the post-processing using the plasma post-processing apparatus RPA (see FIG. 1) according to the disclosure.

The display panel DP may include a base layer BL, a circuit element layer DP-CL, a display element layer DP-OLED, and an encapsulation layer EC.

The base layer BL may provide a base surface on which the circuit element layer DP-CL is disposed. The circuit element layer DP-CL may be disposed on the base layer BL. The circuit element layer DP-CL may include an insulating layer, a semiconductor pattern, a conductive pattern, a signal line, and the like within the spirit and the scope of the disclosure. The insulating layer, the semiconductor layer, and the conductive layer may be formed on the base layer BL in a technique such as coating, deposition, and the like, and, the insulating layer, the semiconductor layer, and the conductive layer may be selectively patterned via photolithography processes. Thereafter, the semiconductor pattern, the conductive pattern, and the signal line included in the circuit element layer DP-CL may be formed.

At least one inorganic layer is formed on a top surface of the base layer BL. The inorganic layer may contain at least one of an aluminum oxide, a titanium oxide, a silicon oxide, a silicon oxynitride, a zirconium oxide, and a hafnium oxide. The inorganic layer may be formed in multiple layers. The multiple inorganic layers may constitute a barrier layer and/or a buffer layer. In an embodiment, the display panel DP is shown as including a buffer layer BFL.

The buffer layer BFL may improve a bonding force between the base layer BL and the semiconductor pattern. The buffer layer BFL may include a silicon oxide layer and a silicon nitride layer, and the silicon oxide layer and the silicon nitride layer may be alternately stacked each other.

The semiconductor pattern may be disposed on the buffer layer BFL. The semiconductor pattern may contain polysilicon. However, the disclosure may not be limited thereto, and the semiconductor pattern may contain amorphous silicon or a metal oxide.

FIG. 10 shows some of the semiconductor pattern, and semiconductor patterns may be further disposed in another region. The semiconductor patterns may be arranged or disposed in a given rule across pixels. The semiconductor pattern may have different electrical properties depending on whether it is doped or not. The semiconductor pattern may include a first region having high conductivity and a second region having low conductivity. The first region may be doped with an N-type dopant or a P-type dopant. A P-type transistor may include a dopped region doped with the P-type dopant. The second region may be a non-doped region or may be doped at a lower concentration than the first region.

The conductivity of the first region is greater than that of the second region, and the first region substantially serves as an electrode or the signal line. The second region may substantially correspond to an active region (or a channel region) of a transistor. In other words, a portion of the semiconductor pattern may be the active region of the transistor, and another portion may be a source region or a drain region of the transistor. Each of the pixels may have an equivalent circuit including seven transistors, one capacitor, and a light emitting element, and the equivalent circuit diagram of the pixel may be modified in various forms. FIG. 10 illustrates one transistor TR and a light emitting element ED included in the pixel.

A source region SR, a channel region CHR, and a drain region DR of the transistor TR may be formed from the semiconductor pattern. The source region SR and the drain region DR may be arranged or disposed on opposite sides around the channel region CHR on the cross-section. FIG. 10 illustrates a portion of a signal line SCL disposed on a same layer as the semiconductor pattern. Although not shown separately, the signal line SCL may be electrically connected to the transistor TR on a plane.

A first insulating layer IL1 may be disposed on the buffer layer BFL. The first insulating layer IL1 may overlap the pixels and cover the semiconductor pattern. The first insulating layer IL1 may be an inorganic layer and/or an organic layer, and may have a single-layer or multi-layer structure. The first insulating layer IL1 may contain at least one of the aluminum oxide, the titanium oxide, the silicon oxide, the silicon nitride, the silicon oxynitride, the zirconium oxide, and the hafnium oxide. In an embodiment, the first insulating layer IL1 may be a single-layer silicon oxide layer. An insulating layer of the circuit element layer DP-CL to be described later as well as the first insulating layer IL1 may be the inorganic layer and/or the organic layer, and may have the single-layer or multi-layer structure. The inorganic layer may contain at least one of the above-mentioned materials, but the disclosure may not be limited thereto.

A gate GE of the transistor TR is disposed on the first insulating layer ILL The gate GE may be a portion of a metal pattern. The gate GE overlaps the channel region CHR. In a process of doping the semiconductor pattern, the gate GE may function as a mask.

A second insulating layer IL2 may be disposed on the first insulating layer IL1 and may cover the gate GE. The second insulating layer IL2 may overlap the pixels. The second insulating layer IL2 may be the inorganic layer and/or the organic layer, and may have the single-layer or multi-layer structure. In an embodiment, the second insulating layer IL2 may be the single-layer silicon oxide layer.

A third insulating layer IL3 may be disposed on the second insulating layer IL2. In an embodiment, the third insulating layer IL3 may be the single-layer silicon oxide layer. A first connection electrode CNE1 may be disposed on the third insulating layer IL3. The first connection electrode CNE1 may be connected to the signal line SCL through a contact hole CNT1 extending through the first, second, and third insulating layers Ill, IL2, and IL3.

A fourth insulating layer IL4 may be disposed on the third insulating layer IL3. The fourth insulating layer IL4 may be the single-layer silicon oxide layer. A fifth insulating layer IL5 may be disposed on the fourth insulating layer IL4. The fifth insulating layer IL5 may be the organic layer.

A second connection electrode CNE2 may be disposed on the fifth insulating layer IL5. The second connection electrode CNE2 may be connected to the first connection electrode CNE1 through a contact hole CNT2 extending through the fourth insulating layer IL4 and the fifth insulating layer IL5.

A sixth insulating layer IL6 may be disposed on the fifth insulating layer IL5 and may cover the second connection electrode CNE2. The sixth insulating layer IL6 may be the organic layer. The display element layer DP-OLED may be disposed on the circuit element layer DP-CL. The display element layer DP-OLED may include the light emitting element ED. For example, the display element layer DP-OLED may contain an organic light emitting material, a quantum dot, a quantum rod, a micro LED, or a nano LED. The light emitting element ED may include a first electrode AE, a light emitting layer EL, and a second electrode CE.

The first electrode AE may be disposed on the sixth insulating layer IL6. The first electrode AE may be connected to the second connection electrode CNE2 through a contact hole CNT3 extending through the sixth insulating layer IL6.

A pixel defining layer IL7 may be disposed on the sixth insulating layer IL6 and may cover a portion of the first electrode AE. A display opening OP7 is defined in the pixel defining layer IL7. The display opening OP7 of the pixel defining layer IL7 exposes at least a portion of the first electrode AE. In an embodiment, a light emitting region PXA is defined to correspond to the partial region of the first electrode AE exposed by the display opening OP7. A non-light emitting region NPXA may surround or may be adjacent to the light emitting region PXA. The non-light emitting region NPXA may be defined as a region overlapping the pixel defining layer IL7.

The light emitting layer EL may be disposed on the first electrode AE. The light emitting layer EL may be disposed in the display opening OP7. For example, the light emitting layers EL may be formed separately from each other in the pixels. In case that the light emitting layers EL are formed separately from each other in the pixels, each of the light emitting layers EL may emit light of at least one color among blue, red, and green. However, the disclosure may not be limited thereto, and the light emitting layers EL may be connected to each other in the pixels and may be integral with each other. The light emitting layer EL may provide blue light or white light.

In the light emitting element ED according to an embodiment, a hole control layer may be disposed between the first electrode AE and the light emitting layer EL. The hole control layer may be commonly disposed in the light emitting region PXA and the non-light emitting region NPXA. The hole control layer may include a hole transport layer and may further include a hole injection layer. An electron control layer may be disposed between the light emitting layer EL and the second electrode CE. The electron control layer may include an electron transport layer and may further include an electron injection layer. The hole control layers and the electron control layers may be formed in the pixels using an open mask.

The encapsulation layer EC may be disposed on the display element layer DP-OLED to cover the light emitting element ED. The encapsulation layer EC may include at least one organic film and at least one inorganic film. The inorganic film may contain an inorganic material and protect the display element layer DP-OLED from moisture or oxygen. The inorganic film may include a silicon nitride layer, a silicon oxynitride layer, a silicon oxide layer, a titanium oxide layer, or an aluminum oxide layer, but the disclosure may not be particularly limited thereto. The organic film may contain an organic material, and may protect the display element layer DP-OLED from foreign substances such as dust particles.

At least one of the first connection electrode CNE1 and the second connection electrode CNE2 included in the circuit element layer DP-CL may include sequentially stacked conductive layers. For example, at least one of the first connection electrode CNE1 and the second connection electrode CNE2 may include three conductive layers, and the lowermost conductive layer and the uppermost conductive layer may contain a same material or a similar material. The lowermost conductive layer and the uppermost conductive layer may contain titanium (Ti), and an intermediate conductive layer may contain aluminum (Al).

FIGS. 11A to 11D show a method for forming the conductive pattern by etching the conductive layer, and FIGS. 11E to 11F show a method for performing the post-processing process via the plasma post-processing apparatus RPA of the disclosure.

Referring to FIG. 11A, an intermediate insulating layer IML and a conductive layer SDL may be formed on the base layer BL. The intermediate insulating layer IML may correspond to one of the first to sixth insulating layers IL1, IL2, IL3, IL4, IL5, and IL6 described with reference to FIG. 10.

The conductive layer SDL may include first to third conductive layers M1, M2, and M3. The first and third conductive layers M1 and M3 may contain a same material or a similar material, and the second conductive layer M2 may contain a material different from that of the first and third conductive layers M1 and M3. For example, the first and third conductive layers M1 and M3 may contain titanium (Ti), and the intermediate second conductive layer M2 may contain aluminum (Al).

Thereafter, referring to FIGS. 11B and 11C, the photoresist layer PR may be formed on the conductive layer SDL. Thereafter, the photoresist layer PR may be patterned via exposure and developing processes on the photoresist layer PR.

Thereafter, referring to FIG. 11D, a step for etching the conductive layer SDL using the patterned photoresist layer PR as a mask may be included. The etching step may be performed in a dry etching method. In this regard, chlorine (Cl₂) may be provided as a process gas for the dry etching. Via the etching process, the conductive layer SDL may form the conductive patterns SD that overlap the patterned photoresist layer PR. In this regard, the chlorine (Cl₂) provided as the process gas may remain on the conductive patterns SD in a form of chlorine ions (Cl⁻), and the chlorine ions (Cl⁻) may cause corrosion of the conductive patterns SD.

The work substrate SUB (see FIG. 1) provided to the plasma post-processing apparatus RPA (see FIG. 1) according to the disclosure may be provided in a state in which the patterned photoresist layer PR and the conductive patterns SD overlapping the same are formed after the etching process is performed.

Referring to FIG. 11E, the plasma post-processing method according to an embodiment may include a corrosion prevention treatment step.

The corrosion prevention treatment step provides the water vapor (H₂O) to the plasma generator RPG (see FIG. 1) to form water vapor (H₂O) plasma. Thereafter, a step of providing the first radicals contained in the water vapor (H₂O) plasma to the transfer pipe DL and spraying the first radicals to the diffuser DF (see FIG. 1) may be included.

The first radicals may be sprayed onto the work substrate SUB (see FIG. 1). The first radicals are combined with the chlorine ions (Cl⁻) remaining on the conductive patterns SD and are discharged to the outside of the chamber CB (see FIG. 1) in the form of hydrochloric acid (HCl).

Thereafter, referring to FIG. 11F, a step of removing the photoresist layer PR may be included. In the step of removing the photoresist layer PR, the oxygen (O₂) is provided to the plasma generator RPG (see FIG. 1) to form oxygen (O₂) plasma. Thereafter, a step of providing the second radicals contained in the oxygen (O₂) plasma to the transfer pipe DL (see FIG. 1) and spraying the second radicals to the diffuser DF (see FIG. 1) may be included.

According to the plasma post-processing method of the disclosure, the corrosion prevention treatment step of the conductive patterns SD formed by the dry etching and the step of removing the photoresist layer PR may be performed in a same chamber CB (see FIG. 1) and may be performed as continuous processes. Accordingly, the plasma post-processing method with simplified processes may be provided.

Hereinabove, the description has been made with reference to the disclosed embodiments, but those skilled in the art or those having ordinary knowledge in the technical field will understand that the disclosure may be variously modified and changed within the spirit and scope of the disclosure and as described in the claims.

Accordingly, the technical scope of the disclosure should be defined by the claims in addition to the contents described in the detailed description of the specification.

According to an embodiment, as the diffuser has the selectable shape, the radicals sprayed from the diffuser may be uniformly sprayed onto the work substrate. As the plasma post-processing apparatus including the diffusers is provided, the radicals may be uniformly sprayed onto the work substrate with the large-area. Accordingly, the plasma post-processing apparatus with the improved dispersion may be provided.

According to an embodiment, as the corrosion prevention treatment step and the step of removing the photoresist layer proceed in a same chamber, the processes may be simplified.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A plasma post-processing apparatus comprising:
a chamber;
a stage disposed inside of the chamber, wherein a work substrate is disposed on the stage;
diffusers each of which increases in width in a direction away from the work substrate and each of the diffusers having holes, and disposed above the stage;
transfer pipes respectively connected to the diffusers; and
plasma generators respectively connected to pipes that supply process gases and are respectively connected to the transfer pipes,
wherein a diameter of the holes defined in a diffuser disposed at a center of the work substrate among the diffusers is less than a diameter of holes defined in each of remaining diffusers among the diffusers.

2. The plasma post-processing apparatus of claim 1, wherein
the diameter of the holes defined in one of the diffusers disposed at the center of the work substrate among the diffusers is substantially equal to or greater than about 2 Φ and substantially equal to or less than about 15 Φ, and
the diameter of the holes defined in each of the remaining diffusers is substantially equal to or greater than about 2 Φ and substantially equal to or less than about 30 Φ.

3. The plasma post-processing apparatus of claim 1, wherein a diameter of each of the holes increases gradually in the direction away from the work substrate.

4. The plasma post-processing apparatus of claim 1, wherein each of the diffusers contains an aluminum oxide.

5. The plasma post-processing apparatus of claim 1, wherein
each of the diffusers includes an outer surface, an inner surface opposite to the outer surface, and a connecting surface disposed between the outer surface and the inner surface,
the holes are defined through the inner surface from the outer surface, and
an internal space is defined inwardly of the inner surface.

6. The plasma post-processing apparatus of claim 5, wherein each of the diffusers has a substantially hemispherical shape substantially convex in a direction toward the work substrate.

7. The plasma post-processing apparatus of claim 5, wherein each of the diffusers has a substantially conical shape substantially convex in a direction toward the work substrate.

8. The plasma post-processing apparatus of claim 1, wherein the process gases provided to the pipes are at least one of water vapor (H₂O), oxygen (O₂), carbon tetrafluoride (CF₄), argon (Ar), nitrogen (N₂), and helium (He).

9. The plasma post-processing apparatus of claim 1, further comprising:
a backing plate having first holes and connected with the diffusers;
an insulator having second holes respectively overlapping the first holes and disposed on the backing plate; and
a cooling plate having third holes respectively overlapping the second holes and disposed on the insulator.

10. The plasma post-processing apparatus of claim 9, wherein one of the transfer pipes is formed with one of the first holes, one of the second holes, and one of the third holes aligned with each other.

11. The plasma post-processing apparatus of claim 1, wherein
at least one of the diffusers includes a first portion where the holes are defined and a second portion extending from the first portion and where the holes are not defined, and
the second portion is connected to a corresponding transfer pipe.

12. A plasma post-processing apparatus comprising:
a chamber;
a stage disposed inside of the chamber, wherein a work substrate is disposed on the stage;
a diffuser having a substantially hemispherical shape substantially convex in a direction toward the work substrate, the diffuser having holes, and disposed above the stage;
a backing plate having a first hole and connected with the diffuser;
an insulator having a second hole overlapping the first hole and disposed on the backing plate;
a cooling plate having a third hole overlapping the second hole and disposed on the insulator; and
a plasma generator connected to pipes that supply process gases, wherein
the first hole, the second hole, and the third hole aligned with each other are defined as a transfer pipe, and
the plasma generator is connected to the transfer pipe.

13. The plasma post-processing apparatus of claim 12, wherein the diffuser contains an aluminum oxide.

14. The plasma post-processing apparatus of claim 12, wherein
the diffuser includes a first portion where the holes are defined and a second portion extending from the first portion and where the holes are not defined, and
the second portion is connected to the transfer pipe.

15. The plasma post-processing apparatus of claim 12, wherein the process gases provided to the pipes are at least one of water vapor (H₂O), oxygen (O₂), carbon tetrafluoride (CF₄), argon (Ar), nitrogen (N₂), and helium (He).

16. The plasma post-processing apparatus of claim 12, wherein a diameter of each of the holes of the diffuser increases gradually in a direction away from the work substrate.

17. The plasma post-processing apparatus of claim 12, wherein
the diffuser includes an outer surface, an inner surface opposite to the outer surface, and a connecting surface disposed between the outer surface and the inner surface and connected to the backing plate,
the holes are defined through the inner surface from the outer surface, and
a substantially hemispherical internal space is defined inwardly of the inner surface.

18. The plasma post-processing apparatus of claim 12, wherein a diameter of the holes is substantially equal to or greater than about 2 Φ and substantially equal to or less than about 30 Φ.

19. A plasma post-processing method comprising:
forming a conductive pattern by etching a conductive layer formed on a work substrate; and
performing a corrosion prevention treatment on the conductive pattern, wherein
the performing of the corrosion prevention treatment includes:
generating first radicals by a plasma generator by receiving water vapor (H₂O); and
providing the first radicals to a transfer pipe and spraying the first radicals by a diffuser,
the diffuser has a substantially hemispherical shape substantially convex in a direction toward the work substrate and has holes.

20. The plasma post-processing method of claim 19, further comprising:
removing a photoresist layer disposed on the conductive pattern, wherein
the removing of the photoresist layer includes:
generating second radicals by the plasma generator by receiving oxygen (O₂); and
providing the second radicals to the transfer pipe and spraying the second radicals to the diffuser,
the performing of the corrosion prevention treatment and the removing of the photoresist layer are performed as continuous processes in a same chamber.
